(19) United States
(12) Patent Application Publication
(10) Pub. No.: US 2008/0048675 A1
(43) Pub. Date: Feb. 28, 2008

(54) A METHOD OF ACCURATELY COMPUTING AMPLITUDE AND PHASE NOISE OF OSCILLATORS AND GENERATING A GENERAL PURPOSE NOISE MODEL OF OSCILLATORS, MIXERS, AND AMPLIFIERS IN FREQUENCY DOMAIN ANALYSIS OF ANALOG ELECTRONIC CIRCUITS AND USING SAME

(75) Inventors: EDOUARD NGOYA, ISLE (FR); JEAN ROUSSET, LIMOGES (FR)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: XPEDION DESIGN SYSTEMS, INC., MILPITAS, CA (US)

(21) Appl. No.: 11/457,143

(22) Filed: Jul. 12, 2006

(51) Int. Cl. G01R 29/26

(52) U.S. Cl. 324/613

(57) ABSTRACT

A method of accurately computing amplitude and phase noise of oscillators and generating a general purpose noise model of oscillators, mixers, and amplifiers in frequency domain analysis of analog electronic circuits and using same. A method for computing amplitude jitter, frequency jitter, sideband noise, and plain phase noise for oscillators, mixers, and amplifiers and modeling these sub-circuits accurately within a frequency domain analysis of an analog electronic circuit.

### BACKGROUND

In conventional simulators, it is possible to model the noise characteristics of oscillators, mixers, and amplifiers either in their complex amplitude perturbations or in their frequency perturbations. Typically users choose one or the other according to their application as the model will be inaccurate either close to the carrier or at an offset. Thus they must choose between two models, neither of which accurately represents the cross correlation between amplitude perturbations and frequency perturbations in noise analysis. As more intellectual property is developed for reuse, the deployers of an oscillator, mixer, or amplifier may not have a sophisticated knowledge of these issues nor is it desirable for intellectual property developers to have to anticipate the application or maintain a plurality of noise models.

Circuit designers are usually interested in viewing the frequency spectrum of noise or the voltage noise spectrum one can view in a spectrum analyzer. Though voltage noise spectrum does not give a valuable quantitative information on phase noise at the vicinity of the carrier frequency, it provides a qualitative view of the oscillator spectral purity. Besides, the spectrum analyzer was the only available instrument to access oscillator noise behavior some years ago. With the new noise measurement instruments one can now directly access the carrier referred amplitude and phase noise without having to extrapolate from a spectrum analyzer plot.

Even though computation of noise spectrum seems simple, this is not the case. The reason for that results from the random nature of noise which does not offer a simple way for computing the actual waveforms, instead we can only access their statistical averages (spectral density). And especially because the statistical distribution of 1/f noise sources (which are the main contributors of noise) is still an unresolved problem, we may not recompose the voltage noise spectrum just from the knowledge of the statistical averages of the carrier referred AM and PM noise δ\hat{v}ₖ(t) and δΩ(t).

There are two types of merit factors for noise, which are on one hand the carrier referred AM and PM noise (δ\hat{v}ₖ(t), δΩ(t)) and on the other hand the voltage noise spectrum. The two types of merit factors have in practice strictly different applications.

The carrier referred AM and PM noise is useful for frequency synthesizer (VCO, Xtall, PLL, Divider) analysis. The specificity of a frequency synthesizer circuit is that it is ought to deliver only a single frequency tone in a bandwidth [−Bw/2,Bw/2] around any carrier harmonic ωₖ. The AM and PM noise will therefore quantify the purity of this expected single tone stimulus.

The voltage noise spectrum is useful for the analysis of transceiver blocs (LNA, Mixer, Converter). The specificity of transceiver blocs is that it is ought to process a signal that is not a single tone, but which occupies a certain bandwidth [−Bw/2, Bw/2]. The voltage noise spectrum is therefore the figure of merit that characterizes the noise superimposed onto the utile signal all over the signal bandwidth, when traversing the circuit (SNR). While the signal delivered by a frequency synthesizer is usually a large amplitude signal, the signal processed by the transceiver bloc is of relatively small amplitude (or equivalently the transceiver is ought to behave linearly enough with respect to the utile signal). Note that in the case of a transceiver bloc, it is common that the transmitted bandwidth is sufficiently far from the LO carrier.

Equivalent Noise Source of a Free Running Oscillator

Assume an oscillator delivers a noisy signal around a fundamental frequency Ω₀

$$u ( t ) = ℜe ( [ {\hat{U}}_{0} + δ \hat{u} ( t ) ] {e}^{j {\int }_{0}^{t} [ {Ω}_{0} + δ Ω ( τ ) ] d τ} )$$

This is characterized by 4 variables which are:

Û₀: nominal complex amplitude (noiseless phasor)

Ω₀: nominal frequency (noiseless frequency)

δû(t): complex amplitude noise component (amplitude jitter)

δΩ(t): frequency noise component (frequency jitter)

It is of importance to clearly isolate the two noise components amplitude jitter δû(t) and frequency jitter δΩ(t) of the oscillator source. These two components are naturally correlated as they share the same origin. It is therefore necessary to measure both their powers and correlation product: <|δû(t)|²>, <|δΩ(t)|²>, <δû(t)δΩ*(t)>.

These three terms can be obtained from the Envelope noise simulation of the oscillator circuit. Note that if the oscillator noise is characterized directly in the form of voltage noise spectrum it is not possible to de-embed the terms δû(t) and δΩ(t). This is a problem for conventional simulators which do not acquire directly amplitude and frequency jitters. The same kind of problem occurs when the phase noise is acquired from measurement equipments. The noise measurement equipment acquires directly the AM and PM terms and also it is not possible to de-embed δû(t) and δΩ(t) contributions. In these situations there is a temptation to ignore one of the two terms, which makes the simulation inaccurate either at frequency offsets close or far from the carrier.

Thus it can be appreciated that what is needed is a way to model an oscillator, mixer, or amplifier in such a way so as to have the model reusable as a component within a system at a broad spectrum of application by analyzing noise characteristics due to frequency perturbations and complex amplitude perturbations and the cross correlation between amplitude and frequency perturbations.

### SUMMARY OF THE INVENTION

The present invention computes, stores, and retrieves the noise characteristics of an oscillator for simulation of a larger system using a method of modeling that is accurate over a broader range of operation.

### BRIEF DESCRIPTION OF FIGURES

FIG. 1 is a graphical illustration of amplitude and phase perturbation of noiseless carrier.

FIG. 2 is a formula and definition of key noise modeling variables.

FIG. 3 is a definition of auxiliary vectors.

FIG. 4 is a description and definition of a noise vector.

FIG. 5A is an expression of the contribution of cross correlation.

FIG. 5B is an expression of the further contribution of cross correlation.

FIG. 5C is an expression of the contribution of frequency correlation.

FIG. 5D is an expression of the contribution of amplitude correlation.

### DETAILED DISCLOSURE

Noise Source Definition Types

The noise source(s) associated to one or a set of voltage sources (or equivalently current sources) is (are) defined by a correlation bloc. The correlation bloc has no network connections; it refers to the associated voltage (or current) sources for the connectivity and large signal levels.

Format: Amplitude and Frequency Jitter

full correlation matrix

$${[ δ {\hat{E}}_{1 , k} ( \overline{ω} ) , δ {\hat{E}}_{1 , - k} ( \overline{ω} ) , … , δ {\hat{E}}_{M , k} ( \overline{ω} ) , δ {\hat{E}}_{M , - k} ( \overline{ω} ) , δ {Ω}_{0} ( \overline{ω} ) ]}^{t} \times [ δ {\hat{E}}_{1 , k} ( \overline{ω} ) , δ {\hat{E}}_{1 , - k} ( \overline{ω} ) , … , δ {\hat{E}}_{M , k} ( \overline{ω} ) , δ {\hat{E}}_{M , - k} ( \overline{ω} ) , δ {Ω}_{0} ( \overline{ω} ) ]$$

is given as a function of noise offset frequency ω̅

An embodiment of the present invention associates a schematic symbol with a sub-circuit which may be an oscillator, mixer, or amplifier. The embodiment further comprises a simulator graphical user interface and an output browser with controls for running the model and downloading results. It will be appreciated by those skilled in the art that the essence of the present invention is computing correlation coefficients in a simulator for reuse as a model of the sub-circuit in a larger system.

Schematic Capture: NOISECOR Symbol

In an embodiment the oscillator noise macromodel is described with a NOISECOR symbol. The NOISECOR is a symbol without any pin, it behaves very much like a mutual inductance bloc. The NOISECOR bloc contains two fields:

one field for the list of the RF sources for which it defines the noise power and correlations. In an embodiment each source is a single tone stimulus and the name of the sources in the list given in the correct order. The RF source will provide information for the carrier tone frequency and amplitude. The other field is the name of file containing the noise source power/correlation information.

Sideband and Frequency Jitter

The full correlation matrix

$${[ δ {\hat{E}}_{1 , k} ( \overline{ω} ) , δ {\hat{E}}_{1 , - k} ( \overline{ω} ) , … , δ {\hat{E}}_{M , k} ( \overline{ω} ) , δ {\hat{E}}_{M , - k} ( \overline{ω} ) , δ {Ω}_{0} ( \overline{ω} ) ]}^{t} \times [ δ {{\hat{E}}^{*}}_{1 , k} ( \overline{ω} ) , δ {{\hat{E}}^{*}}_{1 , - k} ( \overline{ω} ) , … , δ {{\hat{E}}^{*}}_{M , k} ( \overline{ω} ) , δ {{\hat{E}}^{*}}_{M , - k} ( \overline{ω} ) , δ {Ω}_{0}^{*} ( \overline{ω} ) ]$$

is given as a function of noise offset frequency ω̅

Simulator GUI

The Nonlinear noise analysis (amplifier, mixer, oscillator) accepts a plurality of probes in the noise output list to provide for example the phase noise of a VCO+divider at both Vco and divider outputs, and also it is necessary to macromodel a bloc having multiple outputs (e.g. quadrature Vco output). To make the simulation cost effective, it is necessary that each output probe be attached with a single tone frequency. In an embodiment the GUI provides an option for output probe/tone frequency selection.

### Since the cost for noise correlation generation is important, an embodiment of the invention has a button to trigger NOISECOR data generation or not.

Method: Generating the Model—Computing Noise Correlation Data

The present invention is a method for calculating noise correlation information for a sub-circuit.

### Given Q≧1 output probes, each probe Pₖ being specified at a harmonic index (mₖ,nₖ,pₖ), the method comprises calculating the following correlation products

a/—amplitude correlation products

<δ\hat{V}_{q,k}_{_{q}}δ\hat{V}_{o,k}_{ₒ}*>, <δ\hat{V}_{q,k}_{_{q}}δ\hat{V}_{o,-k}_{ₒ}*>, <δ\hat{V}_{q,-k}_{_{q}}δ\hat{V}_{o,k}_{ₒ}*>, <δ\hat{V}_{q,-k}_{_{q}}δ\hat{V}_{o,-k}_{ₒ}*>, q,o=1, . . . , Q, (1)

b/—frequency/amplitude correlation products

<δΩ₀δΩ₀*>, <δ\hat{V}_{q,k}_{_{q}}δΩ₀*>, <δ\hat{V}_{q,-k}_{_{q}}δΩ₀*>, q=1, . . . ,Q. (2)

wherein, computing the frequency/amplitude correlation products (2) occurs on one of the two situations below:
analysis of a free running oscillator, and
analysis of non autonomous circuit (amplifier, mixer, divider) driven by an oscillator noise defined with a full LO noise information (amplitude and frequency jitters),
wherein calculating a correlation product <Xᵢ.Xⱼ*> is based on the adjoint network technique as follows. Each element Xᵢ is expressed via its extraction vector

$${X}_{i} = {p}_{i}^{t} {X}^{1}$$

then the extraction vector p is used as right member of the transposed modified nodal system [Y^{T}]αᵢ=pᵢ. The solutions obtained are finally left and right multiplied to the noise source correlation matrix to obtain the resulting correlation product <XᵢXⱼ*>=αᵢ^{t}<NN*^{t}>αⱼ*^{t}.
Given the δ\hat{V}_{q,k} the output noise voltage corresponding to probe q at tone frequency k. Consider p_{q,k} the extraction vector of δ\hat{V}_{q,k} from the noise solution vector δ\hat{V}

δ\hat{V}_{q,k}( ω̅)=p^{t}_{q,k}δ\hat{V}=p_{q,k}^{t}Y⁻¹[δÛ+δΩ₀.B]
where δΩ₀, δÛ and B are respectively the LO frequency jitter (modulation), the noise source sideband fluctuations and the frequency sensitivity vector of the circuit.

Defining

Y^{t}α_{q,k} @ p_{q,k}

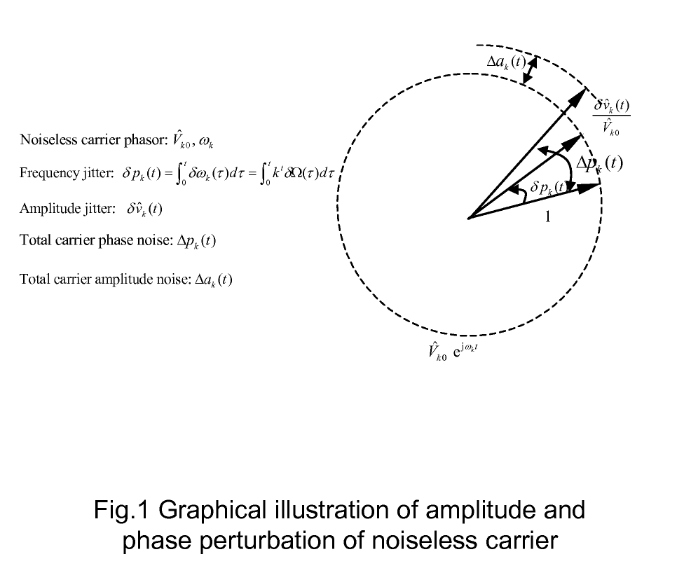

δ @ <[δÛ+δΩ₀]δΩ₀*>
we see that the correlation product <δ\hat{V}_{q,k}δΩ₀*> for any of the probe q and frequency tone k can be computed by the formula

<δ\hat{V}_{q,k}δΩ₀*>=α_{q,k}^{t}Γ
The method further comprises computing vector Γ by inspection, from NOISECOR bloc, following the pattern below.
Given an M≧1 element NOISECOR bloc (FIG. 1), two types of contributions are to be considered in vector Γ.
Contribution type 1: <δÊ_{i,k}_{ᵢ}δΩ₀*>, <δÊ_{i,-k}_{ᵢ}δΩ₀*>, i=1, . . . , M

$$Γ ← \begin{matrix}1 \\ ⋮ \\ {r}_{i , {k}_{i} …} \\ ⋮ \\ {r}_{i , - {k}_{i} …} \\ ⋮\end{matrix} [ \begin{matrix}⋮ \\ ⋮ \\ < δ {\hat{E}}_{i , {k}_{i}} δ {Ω}_{0}^{*} > \\ ⋮ \\ < δ {\hat{E}}_{i , - {k}_{i}} δ {Ω}_{0}^{*} > \\ ⋮\end{matrix} ]$$

r_{i,k}_{ᵢ} and r_{i,-k}_{ᵢ} are the locations of the ith LO source current of the NOISECOR bloc in the noise solution vector, at frequency tones kᵢ and −kᵢ respectively

Contribution type 2:

$$Γ ← < δ {Ω}_{0} δ {Ω}_{0}^{*} > \times [ \begin{matrix} \\ B \\ \end{matrix} ]$$

Noise Format

NOISECOR format is used to model noise of an oscillator. It is the most accurate oscillator noise model. To process this model, the method comprises computing the circuit frequency sensitivity vector B=j[\hat{Q}+\dot{Y}(ω)\hat{V}]. There are as many frequency sensitivity vectors as the number of fundamental frequencies in the analysis (i.e. 1 to 3). The various sensitivity vectors are directly delivered by the harmonic balance (HB) kernel along with the large signal solution vector, as is the case for normal oscillator analysis. The frequency tone of the RF sources associated to the NOISECOR bloc will then indicate the fundamental frequency to be considered. As stated above, it is mandatory that all RF sources associated with a NOISECOR bloc deliver the same frequency tone, besides this tone can only be the fundamental or a harmonic of a fundamental frequency. The only choice for noise format is therefore (h₁,0,0), (0,h₂,0) or (0,0,h₃). Also there may not be two different NOISECOR blocs on the same fundamental frequency, because each of them would define a different period jitter on a single time basis. Note that the corresponding fundamental frequency harmonic rank h_{c} (c=1,2,3) will be used in noise source data processing below.

An M≧1 element NOISECOR bloc defines a correlation matrix containing the following terms.

$$\begin{matrix} < δ {Ω}_{0} δ {Ω}_{0}^{*} > \\ < δ {\hat{E}}_{i , {k}_{i}} δ {Ω}_{0}^{*} > , < δ {\hat{E}}_{i , - {k}_{i}} δ {Ω}_{0}^{*} > , i = 1 , … , M \\ < δ {\hat{E}}_{i , {k}_{i}} δ {\hat{E}}_{j , {k}_{j}}^{*} > , < δ {\hat{E}}_{i , {k}_{i}} δ {\hat{E}}_{j , - {k}_{j}}^{*} > , < δ {\hat{E}}_{i , - {k}_{i}} δ {\hat{E}}_{j , {k}_{j}}^{*} > , \\ < δ {\hat{E}}_{i , - {k}_{i}} δ {\hat{E}}_{j , - {k}_{j}}^{*} > , i , j = 1 , … , M\end{matrix}$$

Note that the various tones kᵢ and kⱼ in the above are identical: kᵢ=kⱼ=h, ∀i,j.

The invention applies to either a set of RF voltage sources or a set of RF current sources. It will be appreciated by those skilled in the art that each noise source bloc contributes in the calculation of every correlation term selection following an adjoint network inspection strategy.

Given <δaδb*^{t}>=pₐ^{t}Y⁻¹<δUδU*^{t}>(Y⁻¹)*^{t}p_{b}*=αₐ^{t}<δUδU*^{t}>α_{b}* the correlation term to be computed, the NOISECOR bloc will directly contribute in the right hand vector β_{b}=<δUδU*^{t}>α_{b}* Recalling that pₐ and p_{b} are extraction vectors of variables δa, the method comprises obtaining vectors αₐ and α_{b} by solving the adjoint nodal admittance systems Y^{t}αₐ=pₐ and Y^{t}α_{b}=p_{b}.

### The contributions of NOISECOR to β_{b}=<δUδU*^{t}>α_{b}* are depicted below for voltage and current source sets.

Voltage Sources

Defining r_{i,k} the row rank of the ith LO source current of the NOISECOR bloc, in the noise solution vector, at frequency tone k, we have the contribution vectors.

$$\begin{matrix}\begin{matrix}\begin{matrix}1 \\ ⋮ \\ {r}_{i , k …} \\ ⋮\end{matrix} [ \begin{matrix}⋮ \\ ⋮ \\ < δ {\hat{E}}_{i , k} δ {\hat{E}}_{j , l}^{*} > {α}_{b}^{*} [ {r}_{j , l} ] \\ ⋮\end{matrix} ] \\ i , j = 1 , … , M ; k , l = \pm h\end{matrix} & \begin{matrix}\begin{matrix}1 \\ ⋮ \\ {r}_{i , k …} \\ ⋮\end{matrix} [ \begin{matrix}⋮ \\ ⋮ \\ \frac{1}{{h}_{c}} < δ {\hat{E}}_{i , k} δ {Ω}_{0}^{*} > {B}^{{*}_{t}} {α}_{b}^{*} \\ ⋮\end{matrix} ] \\ i = 1 , … , m ; k = \pm h\end{matrix} \\ \begin{matrix}\frac{1}{{h}_{c}} < δ {Ω}_{0} δ {\hat{E}}_{i , k} > {α}_{b}^{*} [ {r}_{i , k} ] \times [ \begin{matrix} \\ B \\ \end{matrix} ] \\ i = 1 , … , m ; k = \pm h\end{matrix} & \frac{1}{{h}_{c}^{2}} < δ {Ω}_{0} δ {Ω}_{0}^{*} > {B}^{{*}_{t}} {α}_{b}^{*} \times [ \begin{matrix} \\ B \\ \end{matrix} ]\end{matrix}$$

Current Sources

Defining n_{i1,k} and n_{i2,k} the incident nodes of the ith LO source of the NOISECOR bloc, in the noise solution vector, at frequency tone k, we have the contributions.

$$\begin{matrix}\begin{matrix}\begin{matrix}1 \\ ⋮ \\ {n}_{i 1 , k …} \\ ⋮ \\ {n}_{i 2 , k …} \\ ⋮\end{matrix} [ \begin{matrix}⋮ \\ ⋮ \\ + < δ {\hat{I}}_{i , k} δ {\hat{I}}_{j , l}^{*} > {α}_{b}^{*} [ {r}_{j , l} ] > \\ ⋮ \\ - < δ {\hat{I}}_{i , k} δ {\hat{I}}_{j , l}^{*} > {α}_{b}^{*} [ {r}_{j , l} ] > \\ ⋮\end{matrix} ] \\ i , j = 1 , … , M ; k , l = \pm h\end{matrix} & \begin{matrix}\begin{matrix}1 \\ ⋮ \\ {n}_{i 1 , k …} \\ ⋮ \\ {n}_{i 2 , k …} \\ ⋮\end{matrix} [ \begin{matrix}⋮ \\ ⋮ \\ + \frac{1}{{h}_{c}} < δ {\hat{I}}_{i , k} δ {Ω}_{0}^{*} > {B}^{{*}_{t}} {α}_{b}^{*} \\ ⋮ \\ - \frac{1}{{h}_{c}} < δ {\hat{I}}_{i , k} δ {Ω}_{0}^{*} > {B}^{{*}_{t}} {α}_{b}^{*} \\ ⋮\end{matrix} ] \\ i = 1 , … , m ; k = \pm h\end{matrix} \\ \begin{matrix}\frac{1}{{h}_{c}} < δ {Ω}_{0} δ {\hat{E}}_{i , k} > ( {α}_{b}^{*} [ {n}_{i 1 , k} ] - {α}_{b}^{*} [ {n}_{i 2 , k} ] ) \times [ \begin{matrix} \\ B \\ \end{matrix} ] \\ i = 1 , … , m ; k = \pm h\end{matrix} & \frac{1}{{h}_{c}^{2}} < δ {Ω}_{0} δ {Ω}_{0}^{*} > {B}^{{*}_{t}} {α}_{b}^{*} \times [ \begin{matrix} \\ B \\ \end{matrix} ]\end{matrix}$$

The envelope phase noise analysis technique

The method relies upon the modified nodal equation of periodic or quasi-periodic steady state regimes in frequency and/or time domain.

Given an arbitrary circuit, the frequency domain equilibrium equation can be stated as

$$\{ \begin{matrix} Y ( ω ) V ( ω ) + I ( ω ) + j ω Q ( ω ) + U ( ω ) = 0 \\ ω ∈ S ⋐ i\end{matrix} \qquad ( 1 )$$

where Y(ω), V(ω), I(ω), Q(ω), U(ω) stand respectively for modified nodal admittance matrix, node voltages and impedance element currents, nonlinear currents, charges, and independent voltage and current sources.
We assume that x(t) the time domain waveform of any variable in the equation (1) can be expressed as:

$$x ( t ) = {\sum }_{k} {\tilde{x}}_{k} ( t ) {e}^{j {ω}_{k} t} \\ {\tilde{x}}_{k} ( t ) = {\hat{x}}_{k} ( t ) {e}^{j {P}_{k} ( t )} = {\hat{x}}_{k} ( t ) {e}^{j {\int }_{0}^{t} {k}^{t} δ Ω ( τ ) d τ} \qquad ( 2 \text{-} 1 )$$

where {ωₖ=k^{t}Ω, kεZ^{M}} define the carrier frequency spectrum and, Ω=[Ω₁, . . . , Ω_{L}] the fundamental carrier or oscillation frequency vector, \hat{x}ₖ(t) the band pass envelope (modulation) components of the signal. The latter can be expanded in Fourier series as

$${\hat{x}}_{k} ( t ) = \frac{1}{2 π} {\int }_{- Bw / 2}^{Bw / 2} {\hat{X}}_{k} ( \overline{ω} ) {e}^{j \overline{ω} t} d \overline{ω} \qquad ( 2 \text{-} 2 )$$

### Note that in (2), a clear distinction is made between frequency modulation δωₖ(t)=k^{t}δΩ(t) and complex amplitude (side-band) modulation \hat{x}ₖ(t)

Taking account of (2) into (1) yields the large signal envelope transient equation

$$\{ \begin{matrix}\begin{matrix} Y ( {ω}_{k} + δ {ω}_{k} ( t ) ) {\hat{υ}}_{k} ( t ) + {\hat{i}}_{k} ( t ) + ( {ω}_{k} + δ {ω}_{k} ( t ) ) {\hat{q}}_{k} ( t ) + \\ {\hat{u}}_{k} ( t ) + \dot{Y} ( {ω}_{k} ) \frac{d}{d t} {\hat{υ}}_{k} ( t ) + \frac{d}{d t} {\hat{q}}_{k} ( t ) = 0\end{matrix} \\ δ {ω}_{k} ( t ) = {k}^{t} δ Ω ( t ) \\ t ∈ ℝ \\ k ∈ {ℤ}^{M}\end{matrix} \qquad ( 3 )$$

where R represents an ensemble of real numbers and Z represents an ensemble of integers.
Note that the basic time varying frequency term δΩ(t) can be imposed by an external driving (i.e. FM signal) or be internally generated by the circuit dynamics (i.e. free running oscillator phase noise perturbation).

Equation (3) applies to the calculation of the periodic and quasi-periodic steady state and noise response of any type of circuit (autonomous and non autonomous).

A further simplification of (3) for the case of noise analysis can be obtained as follows. Assume we have reached an hypothetical noiseless equilibrium of the circuit

$$\{ \begin{matrix}{\hat{ v}}_{k} ( t ) = {\hat{V}}_{k} , {\hat{q}}_{k} ( t ) = {\hat{Q}}_{k} , {\hat{i}}_{k} ( t ) = {\hat{I}}_{k} , {\hat{u}}_{k} ( t ) = {\hat{U}}_{k} , δ Ω ( t ) = 0 \\ ∀ t \geq {t}_{s}\end{matrix} \qquad ( 4 )$$

so that we have the steady state Harmonic/spectral balance equation

$$\{ \begin{matrix} Y ( {ω}_{k} ) {\hat{V}}_{k} + {\hat{I}}_{k} + j {ω}_{k} {\hat{Q}}_{k} + {\hat{U}}_{k} = 0 \\ k ∈ ℤ\end{matrix} \qquad ( 5 )$$

### Now let us consider the perturbation of this state from t>t_{S}, changing the stimulus to

ûₖ(t)=Ûₖ+δûₖ(t)

Ω(t)=Ω+δΩ(t)

|δûₖ(t)|=|Ûₖ| and |δΩ(t)|=|Ω| (6)

Considering that δûₖ(t) and δΩ(t) are small and substituting in (3), we find the small signal envelope transient equation:

$$Y ( {ω}_{k} ) δ {\hat{υ}}_{k} ( t ) + j δ {ω}_{k} ( t ) \dot{Y} ( {ω}_{k} ) {\hat{V}}_{k 0} + \dot{Y} ( {ω}_{k} ) \frac{d}{d t} δ {\hat{υ}}_{k} ( t ) + δ {\hat{i}}_{k} ( t ) + j {ω}_{k} δ {\hat{q}}_{k} ( t ) + j δ {ω}_{k} ( t ) {\hat{Q}}_{k 0} + \frac{d}{d t} δ {\hat{q}}_{k} ( t ) + δ {\hat{u}}_{k} ( t ) = 0 \\ {ω}_{k} = {k}^{t} Ω \\ δ {ω}_{k} ( t ) = {k}^{t} δ Ω ( t ) \\ k ∈ {ℤ}^{M} \\ t > {t}_{s} \qquad ( 7 )$$

Considering the Fourier transform of the various variables

$$δ {\hat{u}}_{k} ( t ) = \frac{1}{2 π} \int δ {\hat{U}}_{k} ( \overline{ω} ) {e}^{j \overline{ω} t} d \overline{ω}$$

$$δΩ ( t ) = \frac{1}{2 π} \int δ Ω ( \overline{ω} ) {e}^{j \overline{ω} t} d \overline{ω}$$

$$δ {\hat{v}}_{k} ( t ) = \frac{1}{2 π} \int δ {\hat{V}}_{k} ( \overline{ω} ) {e}^{j \overline{ω} t} d \overline{ω}$$

$$δ {\hat{i}}_{k} ( t ) = \frac{1}{2 π} \int δ {\hat{I}}_{k} ( \overline{ω} ) {e}^{j \overline{ω} t} d \overline{ω}$$

$$δ {\hat{q}}_{k} ( t ) = \frac{1}{2 π} \int δ {\hat{Q}}_{k} ( \overline{ω} ) {e}^{j \overline{ω} l} d \overline{ω}$$

and applying to (7) yields

[Y(ωₖ)+j ω̅\dot{Y}(ωₖ)]δ\hat{V}ₖ( ω̅)+δÎₖ( ω̅)+j[ωₖ+ ω̅]δ\hat{Q}ₖ( ω̅)+j[\hat{Q}ₖ+\dot{Y}(ωₖ)\hat{V}ₖ]k^{t}δΩ( ω̅)+δÛₖ( ω̅)=0

ω̅ε{−Bw/2,Bw/2}

kεZ^{M} (8)

### Note that the differential terms of the nonlinear currents and charges (δÎₖ( ω̅) and δ\hat{Q}ₖ( ω̅)) are known from the noiseless equilibrium (5), so that (9) can be expanded from 1^{st} order Taylor series as below

$$[ Y ( {ω}_{k} ) + j \overline{ω} \dot{Y} ( {ω}_{k} ) ] δ {\hat{V}}_{k} ( \overline{ω} ) + {\sum }_{l} [ \frac{\partial {\hat{I}}_{k}}{\partial {\hat{V}}_{l}} + j ( {ω}_{k} + \overline{ω} ) \frac{\partial {\hat{Q}}_{k}}{\partial {\hat{V}}_{l}} ] δ {\hat{V}}_{l} ( \overline{ω} ) + j [ {\hat{Q}}_{k} + \dot{Y} ( {ω}_{k} ) {\hat{V}}_{k} ] {k}^{t} δ Ω ( \overline{ω} ) + δ {\hat{U}}_{k} ( \overline{ω} ) = 0 \\ \overline{ω} ∈ \{ - Bw / 2 , Bw / 2 \} \\ k ∈ {ℤ}^{M} \qquad ( 9 )$$

Arranging (9) in the matrix form we obtain the final form of envelope frequency domain noise equilibrium equation below.

$$\begin{matrix} & & & k & & & p\end{matrix} \\ \begin{matrix} \\ k \\ \\ p \\ \end{matrix} [ \begin{matrix} & ⋮ & & ⋮ & \\ ⋯ & \begin{matrix}Y ( {ω}_{k} + j \overline{ω} ) + \\ \frac{\partial {\hat{I}}_{k}}{\partial {\hat{V}}_{k}} j ( {ω}_{k} + \overline{ω} ) \frac{\partial {\hat{Q}}_{k}}{\partial {\hat{V}}_{k}}\end{matrix} & ⋯ & \frac{\partial {\hat{I}}_{k}}{\partial {\hat{V}}_{k}} j ( {ω}_{k} + \overline{ω} ) \frac{\partial {\hat{Q}}_{k}}{\partial {\hat{V}}_{k}} & ⋯ \\ & ⋮ & & ⋮ & \\ ⋯ & \frac{\partial {\hat{I}}_{k}}{\partial {\hat{V}}_{k}} j ( {ω}_{k} + \overline{ω} ) \frac{\partial {\hat{Q}}_{k}}{\partial {\hat{V}}_{k}} & ⋯ & \begin{matrix}Y ( {ω}_{k} + j \overline{ω} ) + \\ \frac{\partial {\hat{I}}_{k}}{\partial {\hat{V}}_{k}} j ( {ω}_{k} + \overline{ω} ) \frac{\partial {\hat{Q}}_{k}}{\partial {\hat{V}}_{k}}\end{matrix} & ⋯ \\ & ⋮ & & ⋮ & \end{matrix} ] [ \begin{matrix}δ {\hat{V}}_{- K} ( \overline{ω} ) \\ ⋮ \\ δ {\hat{V}}_{0} ( \overline{ω} ) \\ ⋮ \\ δ {\hat{V}}_{K} ( \overline{ω} )\end{matrix} ] + [ \begin{matrix}- j K [ {\hat{Q}}_{- K} + \hat{Y} ( {ω}_{K} ) {\hat{V}}_{- K} ] \\ ⋮ \\ 0 j [ {\hat{Q}}_{0} + \dot{Y} ( 0 ) {\hat{V}}_{0} ] \\ ⋮ \\ K j [ {\hat{Q}}_{K} + \dot{Y} ( {ω}_{K} ) {\hat{V}}_{K} ]\end{matrix} ] δ Ω ( \overline{ω} ) + [ \begin{matrix}δ {\hat{U}}_{- K} ( \overline{ω} ) \\ ⋮ \\ δ {\hat{U}}_{0} ( \overline{ω} ) \\ ⋮ \\ δ {\hat{U}}_{K} ( \overline{ω} )\end{matrix} ] = 0 \\ \hat{Y} ( \overline{ω} ) δ \hat{V} ( \overline{ω} ) + B δ Ω ( \overline{ω} ) + δ \hat{U} ( \overline{ω} ) = 0 \\ δ \hat{V} ( \overline{ω} ) ∈ {ℂ}^{N \times 2 K + 1} \\ δ Ω ( \overline{ω} ) ∈ {ℂ}^{L} \qquad ( 10 )$$

(10) is a system of N×(2K+1) equations in N×(2K+1)+L unknowns, which can be used for the noise solution of both forced and free running regimes.

### Equation (10) contains two type of variables, the complex amplitude perturbation δ\hat{V}( ω̅) and the fundamental frequency perturbation (or oscillation frequency jitter) δΩ( ω̅).

Note that the vector B in the equation above defines what will be called herein the frequency sensitivity vector of the circuit. B may be termed as the sensitivity of the circuit modified nodal current with respect to the oscillation frequency.
Ŷ( ω̅) defines the frequency domain time varying modified nodal admittance matrix of large signal noise analysis.

Forming and Solving Noise Equation

For a forced regime, oscillation frequency perturbation δΩ( ω̅) is known and equation (10) a square system of N×(2K+1) equations in N×(2K+1) unknowns. For a free running regime however, at least one oscillation frequency perturbation is unknown and we have to account of a circuit autonomy condition to obtain a square system of equations. One of which is found to be

[pᵣ−e^{j2θ}^{ᵣ}p₋ᵣ]^{t}δ\hat{V}( ω̅)=0 (11)

where pᵣ is the extraction vector of any circuit node presenting a non zero voltage amplitude component at the oscillation frequency, and θᵣ is the corresponding voltage phase.

### Note that pᵣ is a vector containing only an entry of one at the node position and oscillation frequency tone and p₋ᵣ is a vector containing only an entry of one at the node position and minus oscillation frequency tone.

Taking account of the above we may thus rewrite the noise equilibrium equation (10) as following

$$Y ( \overline{ω} ) δ X ( \overline{ω} ) = - δ U ( \overline{ω} ) \\ Non autonoumous circuit case δ X ( \overline{ω} ) @ δ \hat{V} ( \overline{ω} ) \\ δ U ( \overline{ω} ) @ δ \hat{U} ( \overline{ω} ) + δ Ω ( \overline{ω} ) B \\ Y ( \overline{ω} ) @ \hat{Y} ( \overline{ω} ) \\ Autonomous circuit case δ X ( \overline{ω} ) @ {[ δ \hat{V} ( \overline{ω} ) , δ Ω ( \overline{ω} ) ]}^{t} \\ δ U ( \overline{ω} ) @ {[ δ \hat{U} ( \overline{ω} ) , 0 ]}^{t} \\ Y ( \overline{ω} ) @ [ \begin{matrix}\hat{ Y} ( \overline{ω} ) & B \\ {p}_{r}^{t} - ( {e}^{j 2 {θ}_{r}} ) {p}_{r}^{t} & 0\end{matrix} ] \qquad ( 12 )$$

The resolution of noise equation is rendered more complex than that of the noiseless equilibrium by the fact that the noise sources can only be characterized in terms of statistical average; one doesn't dispose of the noise source amplitudes and phases. So the only things we can compute out of the noise equation (12) are the statistical averages of the resulting circuit response.

For that we consider the statistical average of both sides in equation (12) to obtain

Y( ω̅)<δX( ω̅)δX( ω̅)*^{t}>Y( ω̅)*^{t}=<δU( ω̅)δU( ω̅)*^{t}> (13)

the statistical average <δU( ω̅)δU( ω̅)*^{t}> also known as the frequency domain correlation matrix of the circuit noise sources (traditional thermal, shot noise, flicker noises and any otherwise defined source). <δX( ω̅)δX( ω̅)*^{t}> is the frequency domain correlation matrix of the resulting noise perturbation at the circuit nodes, as well as oscillation frequency in case of a free running regime. We will term this output noise correlation matrix.
Note that only very few terms are desired in the output noise correlation matrix <δX( ω̅)δX( ω̅)*^{t}>, so to save computation time and memory, we don't solve (13) by brute force approach, but instead of computing directly the desired terms in the output correlation matrix by the so called adjoint matrix technique.

### For that, given a and b two node voltages (or impedance currents) or a node voltage (or impedance current) and an oscillation frequency of interest, for which we would like to compute the fluctuations correlation term <δa δb*>.

For each of these:

we form the extraction vector pₓ which is a vector containing only an entry of one at the desired node position (or impedance current position) or at the oscillation frequency position in solution vector δX( ω̅), depending whether x is a node voltage (or impedance current) or an oscillation frequency.
we solve the adjoint noise equation system Y( ω̅)^{t}αₓ=pₓ and obtain the solution vector αₓ.

For each pair of adjoint noise system solution vector αₐ and α_{b}:

right multiply the noise source correlation matrix <δU( ω̅)δU( ω̅)*^{t}> by the conjugate of the vector α_{b} to obtain the vector β_{b}=<δU( ω̅)δU( ω̅)*^{t}>α_{b}*. (Do not perform a brute force matrix into vector multiplication.)
construct instead β_{b} by inspection, observing the nodal and statistical connectivity of each noise source in the circuit,
multiply vectors αₐ and β_{b} to obtain the scalar <δa δb*>.

As a final summary the process of forming and solving the envelope noise equation is
Acquire the steady state periodic or quasi-periodic solution from any of the following algorithms: harmonic balance, shooting time or finite difference periodic or quasi-periodic steady state equation (eq5); i.e. the node voltages and oscillation frequency {\hat{V}ₖ, k=−K, . . . , K}, Ω given by (4).
Compute the jacobian of the steady state equilibrium equation in frequency domain; i.e. the derivatives of nonlinear current and charge sources

$$\{ \frac{\partial {\hat{I}}_{k}}{\partial {\hat{V}}_{l}} , \frac{\partial {\hat{Q}}_{k}}{\partial {\hat{V}}_{l}} , k , l = - K , … , K \} ,$$

as given by (9)
Form Ŷ( ω̅) the frequency domain modified nodal admittance matrix of large signal noise analysis as described in (9-10).

For a free running oscillator the method further comprises:

computing the frequency sensitivity vector {B=jk[\hat{Q}ₖ+\dot{Y}(ωₖ)\hat{V}ₖ, k=−K, . . . , K} for the circuit autonomy condition (11) the method further comprises
for each two node voltages (or impedance currents) or for a node voltage (or impedance) and oscillation frequency, computing their fluctuations self and cross-correlation <δa δb*> using adjoint system technique as outlined above.

### CONCLUSION

The present invention is an envelope noise simulation method distinguished by discretion of the key components of oscillator noise, i.e. amplitude and oscillation frequency perturbation (δ\hat{V}( ω̅), δΩ( ω̅)) and their correlation, whereby a simulator accurately computes oscillator phase noise and provides a very accurate macro-model for oscillator circuits, as well as for forced circuits.

The present invention is a process of forming and solving an envelope noise equation comprising the steps of
acquiring the steady state periodic or quasi-periodic solution from any of the following algorithms: harmonic balance, shooting time or finite difference periodic or quasi-periodic steady state equation (eq5); i.e. the node voltages and oscillation frequency {\hat{V}ₖ, k=−K, . . . , K}, Ω given by (4);

computing the jacobian of the steady state equilibrium equation in frequency domain; i.e. the derivatives of nonlinear current and charge sources

$$\{ \frac{\partial {\hat{I}}_{k}}{\partial {\hat{V}}_{l}} , \frac{\partial {\hat{Q}}_{k}}{\partial {\hat{V}}_{l}} , k , l = - K , … , K \} ,$$

as given by (9); and
forming Ŷ( ω̅) the frequency domain modified nodal admittance matrix of large signal noise analysis as described in (9-10).

The present invention is a method for extracting amplitude and oscillation frequency jitter from envelope noise equation and output data for the model comprising the steps of

computing the frequency domain noise source correlation matrix of the circuit noise sources (traditional thermal, shot noise, flicker noises and any otherwise defined source;
right multiplying the noise source correlation matrix <δU( ω̅)δU( ω̅)*^{t}> by the conjugate of the vector α_{b} to obtain the vector β_{b}=<δU( ω̅)δU( ω̅)*^{t}>α_{b}*;
and
multiplying vectors αₐ and β_{b} to obtain the scalar <δa δb*> fluctuations correlation term.

The present invention is a method for processing model data to perform a noise analysis by using a sub-circuit noise macro model of an oscillator, mixer, or amplifier comprising computing and saving the circuit frequency sensitivity vector tangibly embodied on a computer readable medium and retrieving the circuit frequency sensitivity vector within a simulation of a larger circuit.

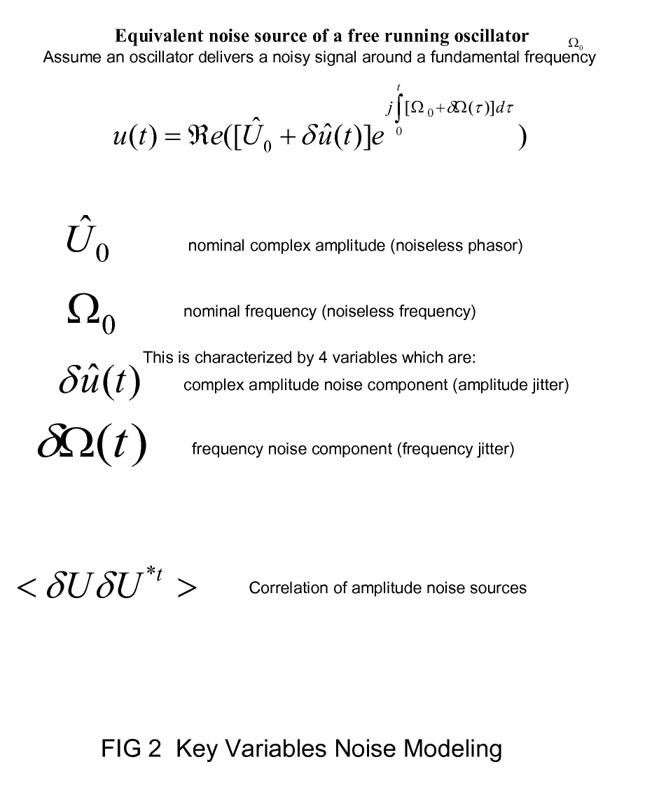

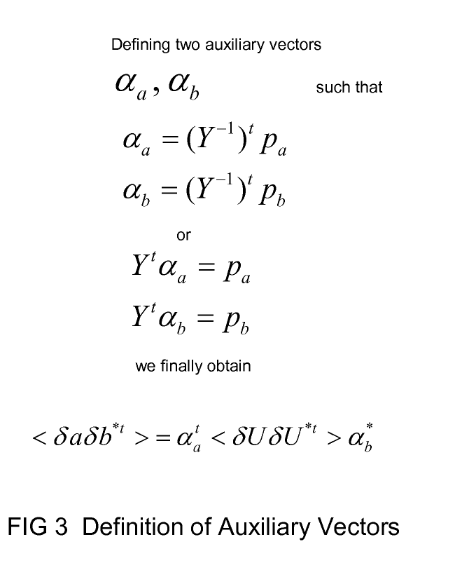

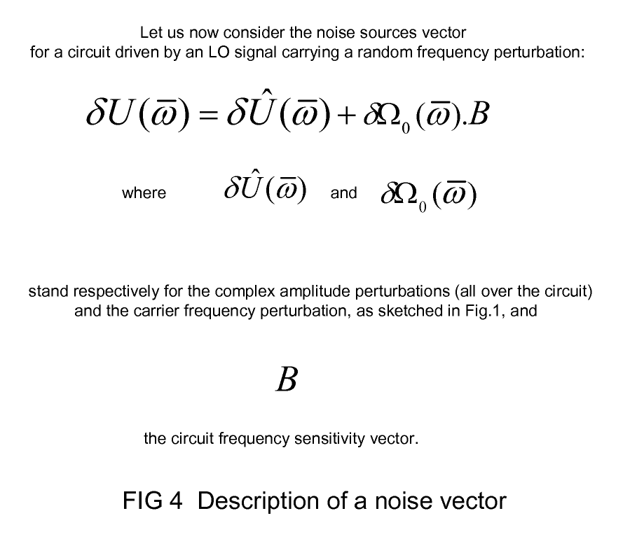

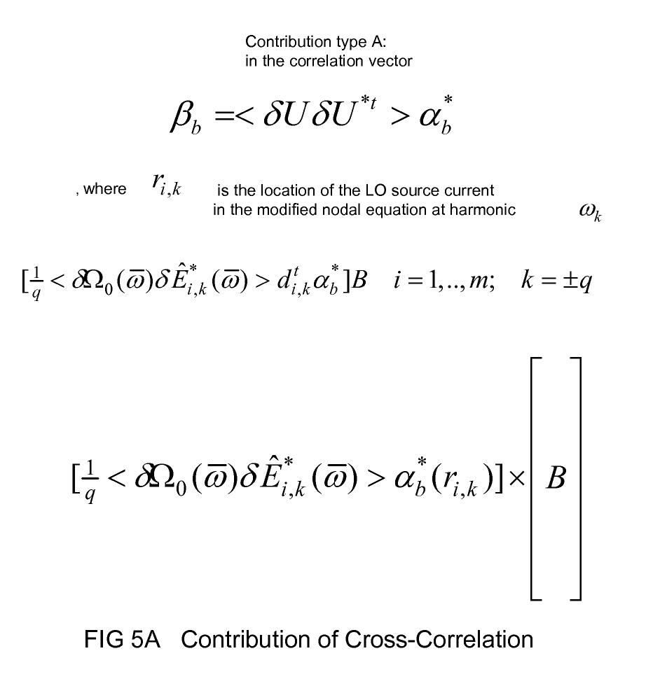

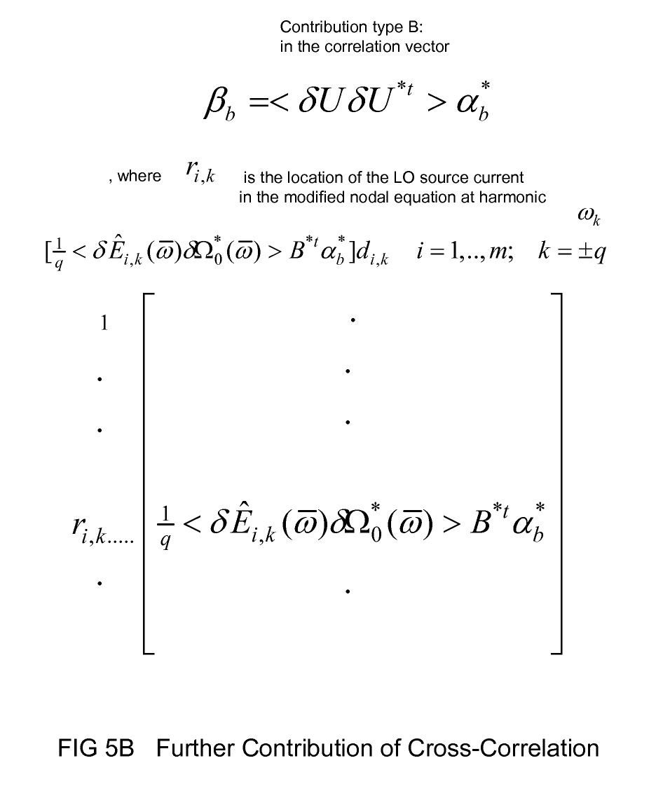

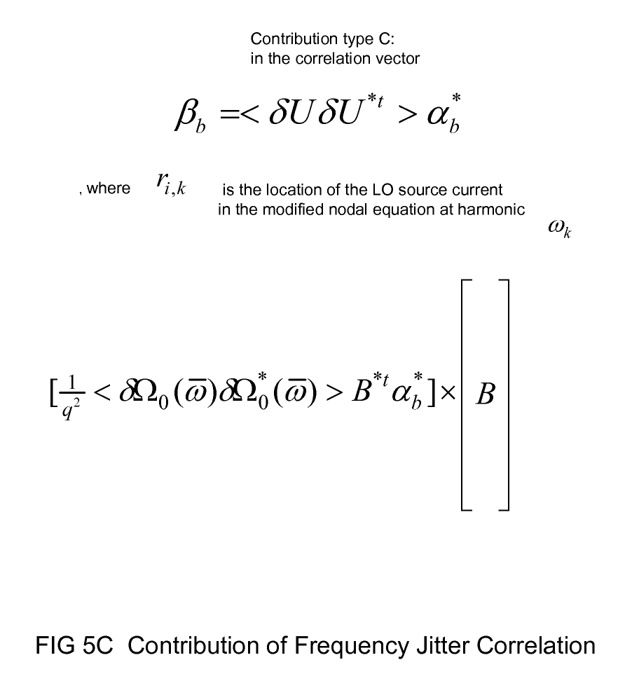

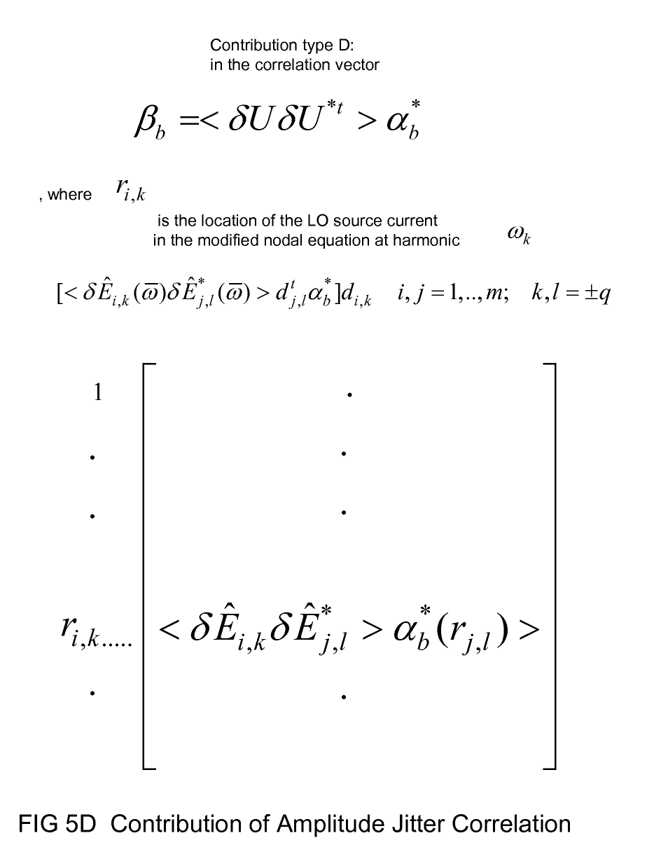

The method comprises the steps following:
computing a correlation of all complex amplitude perturbation sources (FIG. 2),
computing a correlation of all frequency perturbation sources,
computing at least one cross correlation of frequency perturbation and complex amplitude perturbation sources,
computing an adjoint network admittance solution (FIG. 3), and
computing a circuit frequency sensitivity vector (FIG. 4)
   wherein a complex amplitude perturbation source (U) may be one of a plurality of current sources (I) and a plurality of voltage sources (E), further comprising computing and storing a cross-correlation of frequency perturbation and each complex amplitude perturbation source contribution to the correlation vector comprising the step of multiplying the following operands:
an inverse of the harmonic number,
the cross-correlation matrix of frequency perturbation and each complex amplitude perturbation source,
a conjugate of the adjoint network admittance solution, and
the circuit frequency sensitivity vector (FIG. 5A contribution type A).

In the present invention a complex amplitude perturbation source may be one of a plurality of current sources and a plurality of voltage sources, the invention further comprises computing and storing a cross-correlation of each complex amplitude perturbation source and frequency perturbation contribution to the correlation vector comprising the step of multiplying the following operands:
an inverse of the harmonic number,
the cross-correlation matrix of each complex amplitude perturbation source and frequency perturbation,
a transposed conjugate of the circuit frequency sensitivity vector, and
a conjugate of the adjoint network admittance solution (FIG. 5B contribution type B).

The invention further comprises the step of computing and storing a frequency correlation contribution to the correlation vector comprising the steps of multiplying the following operands
an inverse of the harmonic number squared,
the correlation matrix of frequency perturbations,
a transposed conjugate of the circuit frequency sensitivity vector,
a conjugate of the adjoint network admittance solution, and
the circuit frequency sensitivity vector (FIG. 5C contribution type C).

The present invention further comprises computing and storing a correlation of each complex amplitude perturbation source contribution to the correlation vector comprising the step of multiplying the following operands:
the correlation matrix of each complex amplitude perturbation source and
a conjugate of the adjoint network admittance solution (FIG. 5D contribution type D).

What is claimed is:

1. The present invention is a process of forming and solving an envelope noise equation comprising the steps of
acquiring the steady state periodic or quasi-periodic solution from at least one of the following algorithms: harmonic balance, shooting time or finite difference periodic or quasi-periodic steady state equation;
computing the jacobian of the steady state equilibrium equation in frequency domain;
computing the derivatives of nonlinear current and charge sources; and
forming the frequency domain modified nodal admittance matrix of large signal noise analysis.

2. The present invention is a method for extracting amplitude and oscillation frequency jitter from envelope noise equation and output data for the model comprising the steps of
computing the frequency domain noise source correlation matrix of the circuit noise sources;
right multiplying the noise source correlation matrix by the conjugate of the adjoint network admittance solution vector;
constructing the frequency sensitivity vector of the circuit modified nodal current with respect to the oscillation frequency by inspection,
observing the nodal and statistical connectivity of each noise source in the circuit; and
vector multiplying the adjoint network admittance solution vector and the frequency sensitivity vector of the circuit modified nodal current with respect to the oscillation frequency to obtain the scalar fluctuations correlation term.

3. The method for inserting a sub-circuit noise macro model into system circuit simulation comprising the steps of
inserting a symbol onto a schematic,
setting the name value of a source list and
setting the name value of a noise description file,
wherein the source list is at least one name of an RF source which is a single tone stimulus in the system circuit, and
wherein the noise description file is one of a full correlation matrix given as a function of noise offset frequency, a sideband correlation matrix given as a function of noise offset frequency, and a phase noise plot given as a function of noise offset frequency.

4. The method for performing a nonlinear noise analysis of a sub-circuit comprising the steps of setting a plurality of probes in the phase noise output list the probes selected from the list following: an output of a quadrature voltage controlled oscillator, a divider output of a voltage-controlled oscillator and divider, a voltage-controlled oscillator output of a voltage-controlled oscillator and divider.

5. The method of claim 4 wherein each output probe is attached with a single harmonic index.

6. The method of claim 4 wherein the user interface has a button to trigger data generation.

7. The method for generating a sub-circuit noise macro model of an oscillator, mixer, or amplifier comprising calculating amplitude correlation products of every source with itself and with each other source in the sub-circuit.

8. The method of claim 7 wherein a source is one of a voltage source and a current source.

9. The method of claim 8 further comprising calculating frequency/amplitude correlation products in one of two situations following the sub-circuit is a free running oscillator, and the sub-circuit is a non-autonomous circuit driven by an oscillator defined with full local oscillator noise information wherein a non-autonomous circuit comprises one of an amplifier, a mixer, and a divider.

10. The method of computing a full local oscillator noise contribution comprising the steps of
i. expressing each element of the correlation product via its extraction vector,
ii. using the extraction vector as a right member of a transposed modified nodal system, and
iii. left and right multiplying the solutions to the noise source correlation matrix to obtain the resulting correlation product.

11. The method for using a sub-circuit noise macro model of an oscillator, mixer, or amplifier comprising computing and saving the circuit frequency sensitivity vector tangibly embodied on a computer readable medium and retrieving the circuit frequency sensitivity vector within a simulation of a larger circuit.

12. The method comprising the steps following:
computing a correlation of all complex amplitude perturbation sources (FIG. 2),
computing a correlation of all frequency perturbation sources,
computing at least one cross correlation of frequency perturbation and complex amplitude perturbation sources,
computing an adjoint network admittance solution (FIG. 3), and
computing a circuit frequency sensitivity vector (FIG. 4)
wherein a complex amplitude perturbation source (U) may be one of a plurality of current sources (I) and a plurality of voltage sources (E), further comprising computing and storing a cross-correlation of frequency perturbation and each complex amplitude perturbation source contribution to the correlation vector comprising the step of multiplying the following operands:
an inverse of the harmonic number,
the cross-correlation matrix of frequency perturbation and each complex amplitude perturbation source,
a conjugate of the adjoint network admittance solution, and
the circuit frequency sensitivity vector (FIG. 5A contribution type A).

13. The method of claim 12 wherein a complex amplitude perturbation source may be one of a plurality of current sources and a plurality of voltage sources, further comprising computing and storing a cross-correlation of each complex amplitude perturbation source and frequency perturbation contribution to the correlation vector comprising the step of multiplying the following operands:
an inverse of the harmonic number,
the cross-correlation matrix of each complex amplitude perturbation source and frequency perturbation,
a transposed conjugate of the circuit frequency sensitivity vector, and
a conjugate of the adjoint network admittance solution (FIG. 5B contribution type B).

14. The method of claim 12 further comprising the step of computing and storing a frequency correlation contribution to the correlation vector comprising the steps of multiplying the following operands
an inverse of the harmonic number squared,
the correlation matrix of frequency perturbations,
a transposed conjugate of the circuit frequency sensitivity vector,
a conjugate of the adjoint network admittance solution, and
the circuit frequency sensitivity vector (FIG. 5C contribution type C).

15. The method of claim 12 wherein a complex amplitude perturbation source may be one of a plurality of current sources and a plurality of voltage sources, further comprising computing and storing a correlation of each complex amplitude perturbation source contribution to the correlation vector comprising the step of multiplying the following operands:
the correlation matrix of each complex amplitude perturbation source and
a conjugate of the adjoint network admittance solution (FIG. 5D contribution type D).
